(19) United States
(12) Patent Application Publication
(10) Pub. No.: US 2007/0047635 A1
(43) Pub. Date: Mar. 1, 2007

(54) Signaling system with data correlation detection

(76) Inventors: Vladimir M. Stojanovic, Lexington, MA (US); Andrew Ho, Palo Alto, CA (US); Fred F. Chen, San Francisco, CA (US); Simon Li, Sunnyvale, CA (US)

Correspondence Address: SHEMWELL MAHAMEDI LLP, 4880 STEVENS CREEK BOULEVARD, SUITE 201, SAN JOSE, CA, 95129, US

(21) Appl. No.: 11/211,351

(22) Filed: Aug. 24, 2005

(51) Int. Cl. H03H 7/30; H04L 27/06

(52) U.S. Cl. 375/229; 375/343

(57) ABSTRACT

Conditionally updating equalization tap weights within an equalized signaling system based on a measure of correlation that indicates a difference between the number of received data values that have matching bits at a first pair of predetermined bit positions, and the number of received data values that have non-matching bits at the first pair of predetermined bit positions.

### FIELD OF THE INVENTION

The present invention relates to high speed signaling within and between integrated circuit devices.

### BACKGROUND

In adaptively equalized signaling systems, equalization settings are continually adapted based on iterative measurements of incoming signal levels. Because such continual adaptation, in effect, assumes that the incoming signal carries all possible frequency content and ISI patterns, any periodic, repeated data patterns that lack a portion of the possible frequency content or ISI patterns may bias or distort equalization settings. For example, in some systems, a predetermined data pattern may be repeatedly transmitted during idle periods. If the predetermined data pattern lacks a portion of the possible frequency content or ISI patterns that may otherwise appear during random data transmission, a continuous-adaptation signaling system may adapt non-optimal equalization settings that correspond to the limited frequency content or ISI patterns of the predetermined data pattern, increasing the likelihood of bit errors when the idle period ends and transmission of full-spectrum data begins.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates an embodiment of a signaling system having a correlation detection function;

FIG. 2 illustrates an embodiment of a buffer that may be used to implement the storage buffer depicted in FIG. 1;

FIG. 3 illustrates an embodiment of an update filter that may be used to implement update filter of FIG. 1;

FIG. 4 illustrates a manner of measuring correlation between tap data bits and potentially correlated bits within a sequence of validated data snapshots.

FIG. 5 illustrates a conceptual generation of a correlation measure and comparison of the correlation measure with a correlation threshold;

FIG. 6 is a plot of exemplary correlation measures that may be generated according to the principles discussed in reference to FIGS. 4 and 5;

FIG. 7 illustrates an embodiment of a correlation detector that may be used to implement the correlation detector of FIG. 1; and

FIG. 8 illustrates an embodiment of a finite state machine that may be used to implement the finite state machine of FIG. 1.

### DETAILED DESCRIPTION

In the following description and in the accompanying drawings, specific terminology and drawing symbols are set forth to provide a thorough understanding of the present invention. In some instances, the terminology and symbols may imply specific details that are not required to practice the invention. For example, the interconnection between circuit elements or circuit blocks may be shown or described as multi-conductor or single conductor signal lines. Each of the multi-conductor signal lines may alternatively be single-conductor signal lines, and each of the single-conductor signal lines may alternatively be multi-conductor signal lines. Signals and signaling paths shown or described as being single-ended may also be differential, and vice-versa. Similarly, signals described or depicted as having active-high or active-low logic levels may have opposite logic levels in alternative embodiments. As another example, circuits described or depicted as including metal oxide semiconductor (MOS) transistors may alternatively be implemented using bipolar technology or any other technology in which a signal-controlled current flow may be achieved. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘ <̅s̅i̅g̅n̅a̅l̅ n̅a̅m̅e̅>̅’) is also used to indicate an active low signal. The term “coupled” is used herein to express a direct connection as well as a connection through one or more intervening circuits or structures. The term “exemplary” is used to express an example, not a preference or requirement.

Signaling systems and signaling system components capable of measuring correlation in a sequence of received data values and conditionally updating equalizer settings according to the correlation measure are disclosed in various embodiments. In one embodiment, an integrated circuit (IC) device includes a receiver to generate a sequence of multi-bit data values and a correlation detector that compares selected pairs of bits within each of the data values to generate a set of correlation values. The IC also includes an update circuit to generate one or more update values that are conditionally applied to adjust tap weights used within a transmit-side or receive-side equalization circuit. More specifically, in a particular embodiment, each of the correlation values that correspond to a given update value is compared with a correlation threshold. If any of the correlation values exceed the correlation threshold, the corresponding update value is deemed to have been generated based on excessively correlated data and therefore discarded without being applied to update the corresponding tap weight. If all the correlation values that correspond to the update value are below the correlation threshold, thus indicating tolerable (or negligible) data correlation, the update value may be applied to update the tap weight.

In one embodiment, the correlation detector includes a number of correlation cells each coupled to receive a respective pair of bits within an incoming data value and having circuitry to generate a correlation value that indicates, for a given sequence of incoming data values, a difference between the number of data values that have matching bits and the number of data values that have non-matching bits. For example, in a specific implementation, each correlation cell includes an exclusive OR gate (or exclusive NOR gate) to generate an indication of whether a selected pair of bits is the same or different (i.e., compare the bits), and a sign-magnitude counter that is incremented or decremented in response to the exclusive OR result. By this arrangement, assuming the counter is initially reset to zero, the magnitude of the count value maintained by the counter indicates the difference between the number of same-state (matching) bits and the number of different-state (non-matching) bits. If the subject pairs of bits are completely uncorrelated, the number of same-state bits and different-state bits should be nominally the same (e.g., within a statistically expected deviation determined according to the number of compared bit pairs) so that the count magnitude will be zero or near zero. By contrast, if the bit pairs are positively or negatively correlated (i.e., number of the same-state bits or different-state bits exceeds the statistically expected deviation), the count magnitude will be increased according to the degree of correlation. Thus, the count magnitude constitutes a measure of correlation which may be compared with the correlation threshold to determine whether the data correlation is excessive and, if so, to prevent application of a corresponding tap weight update. In alternative embodiments, each correlation cell may count only same-state bits or only different-state bits, with the difference between the number of same-state bits and different-state bits being indicated inferentially. For example, if K bit pairs are compared to generate a given correlation value, and M same-state bit pairs are counted, then the difference between the number of same-state bits and different-state bits is inferentially indicated to be 2M−K. In such an embodiment, the count value, M, may be compared with upper and lower correlation thresholds that bound a tolerable difference between same-state and different-state bits to determine whether to enable or prevent the corresponding tap weight update to be applied. In yet other embodiments, separate counts of same-state and different-state bits may be generated and compared with a correlation threshold, in which case the difference between same-state and different-state bits is indicated by the difference between the two count values. Also, in all such embodiments, the correlation threshold (or multiple correlation thresholds) may be programmed within a configuration register of the host IC or other IC (i.e., any device capable of directly or indirectly delivering correlation thresholds to the correlation detector 129) to allow correlation tolerances to be preset or dynamically adjusted according to application needs.

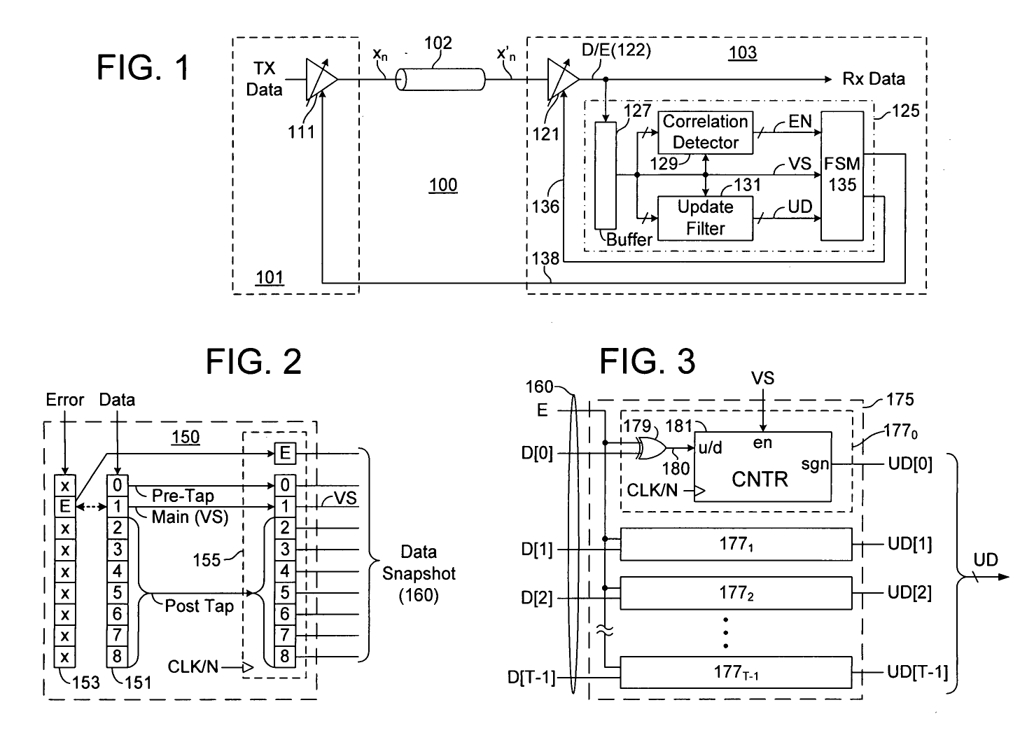

FIG. 1 illustrates an embodiment of a signaling system 110 having a correlation detection function. The signaling system 100 includes a pair of IC devices 101 and 103 coupled to one another via a signaling channel 102. IC 101 includes one or more transmit circuits 111 and is referred to herein as the transmit IC, and IC 103 includes one or more receive circuits 121 and is referred to as the receive IC. Despite this designation, the transmit IC 101 may have any number of receive circuits 121 (or other types of receive circuits) and the receive IC 103 may have any number transmit circuits 111 (or other types of transmit circuits). Also, a given transmit circuit/receive circuit pair within the transmit IC 101 and/or receive IC 103 may be coupled to the same input/output (I/O) node of the IC, thus forming a signal transceiver. The signaling channel 102 may be a single-ended or differential signaling link for conducting electrical or optical signals, and may also be a wireless channel as, for example and without limitation, in the case of RF signaling, capactively-coupled signaling and/or inductively-coupled signaling. Further, in alternative embodiments, the IC devices 101, 103 and signaling channel 102 may be combined within a single integrated circuit package (e.g., forming a multi-chip module, system-in-package (SIP) or the like) or the circuitry formed on the IC devices 101, 103 may be integrated onto a single IC die with the signal channel 102 formed by one or more conductive layers or other structure coupled between regions of the IC die, as in the case of a system-on-chip (SOC).

The receive and transmit circuits (121, 111) may be binary signaling circuits for transmission and reception of binary-encoded signals. In other embodiments, the receive and transmit circuits may be multi-level signaling circuits for transmitting and receiving multi-level signals that convey more than one bit per transmitted symbol (i.e., bit rate greater than baud rate). In yet other embodiments, the receive and transmit circuits may be programmably configured to operate in either a binary signaling or multi-level signaling mode, or may dynamically switch between binary and multi-level signaling modes according to signaling conditions and/or bandwidth requirements.

In one embodiment, at least one of the transmit circuit 111 and receive circuit 121 includes equalizing circuitry to compensate for channel-induced attenuation and ISI (intersymbol interference). For example, in a particular implementation, the transmit circuit 111 includes transmit pre-emphasis circuitry to adjust the level of a signal, xₙ, used to convey a given transmit data value (TX Data) according to previously transmitted, currently transmitted, and yet-to-be transmitted data values. Similarly, the receive circuit 121 may include a decision feedback equalizer and/or linear equalizer to adjust the level of an incoming signal, x′ₙ (a time-delayed, channel-transformed version of the xₙ signal), and/or the operation of circuitry used to amplify or sample the received signal. In one embodiment, the equalizer circuit, whether included within transmit circuit 111 or receive circuit 121, includes a plurality of equalizing signal drivers, referred to herein as equalizing taps, that adjust the xₙ or x′ₙ signal level (or bias points or other operational characteristics of circuits used to amplify or sample the incoming signal) according to the data being conveyed in a given symbol transmission interval (main data), data conveyed in previous transmission intervals (post-tap data) and/or data to be conveyed in subsequent symbol transmission intervals (pre-tap data). The contribution of the main data, post-tap data and pre-tap data to a given signal level, bias point or other operational characteristic is controlled by a set of scaling factors referred to herein as tap weights. In one embodiment, each tap weight applied within a given equalizing circuit has a sign and a magnitude that control the contribution of the equalizer tap (other tap weight formats may be used in alternative embodiments). For example, a transmit pre-emphasis equalizer may include a main-tap driver that contributes to an outgoing signal level according to a main tap weight W[n] and the data value D[n] to be transmitted in a given symbol transmission interval, n; one or more post-tap drivers that contribute to the outgoing signal level according to respective post-tap weights W[n−1]-W[n−x] and previously transmitted data values, D[n−1]-D[n−x] (n−1 being the symbol transmission interval of the most recently transmitted post-tap data, and n−x being the symbol transmission interval of the least-recently or most latent post-tap data); and one or more pre-tap drivers that contribute to the outgoing signal level according to respective pre-tap weights W[n+1]-W[n+y] and yet-to-be transmitted data values, D[n+1]-D[n+y] (n+1 being the symbol transmission interval of the pre-tap data next to be transmitted, and n+y being the symbol transmission interval of the last-to-be transmitted pre-tap data). Similarly, a receive-side equalizer (e.g., linear equalizer and/or decision feedback equalizer) may include any number of post-tap drivers to adjust an incoming signal level (and/or bias points or other operating characteristics of signal amplifying or sampling circuitry) according to already-received data values (i.e., post-tap data values) and corresponding tap weights.

In the signaling system 100 of FIG. 1, the receive IC 103 includes a tap weight adaptation circuit 125 to adaptively update tap weights applied within the transmit circuit 111 and/or receive circuit 121 based on error information recovered by the receive circuit 121. More specifically, in one embodiment, the receive circuit 121 includes a data sampling circuit error sampling circuit that sample the incoming signal in response to a clock signal (which may include multiple clock phases to enable multi-data rate detection, such as double-data rate, quad data rate and so forth) to generate corresponding data and error samples 122 (D/E). The tap weight adaptation circuit 125 includes a buffer circuit 127 that is loaded serially with a predetermined quantity of data and error samples (i.e., collectively forming a multi-bit data word referred to herein as a data snapshot) as well as a correlation detector 129, update filter 131 and finite state machine 135 (FSM). In one embodiment, the update filter 131 generates a time-averaged set of update values (UD) based on a sequence of validated data snapshots (i.e., data snapshots for which a validity signal (VS) is asserted) received from the buffer circuit 127, and the correlation detector 129 generates a corresponding set of update enable signals (EN) based on the sequence of validated data snapshots. The finite state machine 135 counts the number of assertions of the validity signal and, upon determining that a predetermined number of valid data snapshots (which number may be a programmed setting within a configuration register of the receive IC 103) have been applied within the correlation detector 129 and update filter 131, conditionally applies the filtered update signals (UD) to a set of equalizer tap weights according to whether the corresponding enable signals (EN) are asserted. In an alternative embodiment, the finite state machine 135 may refrain from applying any of the update signals if one or more of the enable signals is deasserted. Also, in such an embodiment, the finite state machine 135 may record filtered update signals for which enable signals are asserted so that a full set of filtered update signals may include constituent filtered update signals generated based on different sets of data snap shots. This operation is described in further detail below.

In one embodiment, tap weights are maintained within the FSM 135 and supplied via paths 136 and/or 138 to equalizer taps within the receive circuit 121 and/or transmit circuit 111, respectively. In an alternative embodiment, a set of tap weight registers (or tap weight counters) may be maintained within the transmit IC 101 so that only tap weight update signals (qualified by the update enable signals) need be communicated via signal path 138. Signal path 138 is referred to herein as a back channel and may be implemented, for example, by a signal channel that is physically distinct from signaling channel 102 or by logical partitioning of signaling channel 102 (e.g., out-of-band signaling over signaling channel 102 in the unused code space of a signal encoding scheme).

FIG. 2 illustrates an embodiment of a buffer 150 that may be used to implement buffer 127 of FIG. 1. The buffer includes a pair of serial shift registers 151 and 153, and a snapshot buffer 155. Data samples and error samples (collectively, D/E 122) generated by receive circuit 121 of FIG. 1 are serially loaded into the shift registers 151 and 153 in response to a receive clock signal (CLK, not shown). The receive clock signal may be recovered using timing information within the received data signal itself, for example, using clock-data recovery (CDR) techniques. Also, the receive clock signal may be a multi-phase clock signal to enable multi-data rate signal transmission and reception. In the case of a multi-phase clock signal, data and error samples may be shifted into the shift registers in response to multiple phase-related clock signals so that the shift registers are effectively loaded at a frequency that exceeds the cycle time of any single phase of the multi-phase clock signal. For ease of explanation, the rate at which data and error samples are loaded into shift registers 151 and 153 is referred to herein as the receive clock rate (i.e., frequency of CLK), though in actuality the shift register load rate may be some factor, P, times the receive clock frequency, where P is the number of receive clock phases that are used to trigger sampling of the incoming data signal, x′ₙ.

In one embodiment, the data shift register 151 is at least deep enough to hold a data snapshot that includes the pre-tap, main and post-tap data that is to be evaluated within the correlation detector 129 and to be filtered within the update filter 131. The error shift register 153 may have the same depth (i.e., number of storage elements) as the data shift register 151, or may be small enough to store only the needed error sample (or error samples). In the embodiment of FIG. 2, the error sample (E) captured concurrently (i.e., simultaneously or at least partly overlapping in time) with the main data sample (sample ‘1’ within shift register 151) constitutes an error sample that is supplied to the update filter 131 for generation of filter tap weight updates (UD), and the other error samples (indicated by ‘x’) are ignored. In alternative embodiments, two or more error samples within the error shift register 153 may be supplied to the update filter 131 and used to generate the filtered tap weight update values. Also, in one embodiment, the number of pre-tap and post-tap data values stored within data shift register 151 is programmable (i.e., effected through storage of a configuration value within a configuration register of the receive IC 103) so that the storage element of the data shift register 151 that stores the main data value may be changed according to the configuration value. For example, if the receive IC 103 is configured to apply a single pre-tap data value, the main data value will appear in data shift register element number 1, as shown. If more or fewer pre-tap data values are selected, the main data value will appear at lower-numbered or higher-numbered shift register elements. In such an embodiment, the error sample that corresponds to the main data sample will be stored at higher or lower numbered shift register elements (i.e., according to the location of the main data sample) so that an error shift register having the same depth of the data shift register (or at least as deep as Q+1 storage elements, where Q is the maximum programmable number of pre-tap data values) enables programmable pre-tap/post-tap allocation.

Still referring to FIG. 2, once every N CLK cycles, an interval marked at beginning and end by a snapshot clock signal (CLK/N) and referred to herein as a snapshot interval, the contents of the data shift register 151 (or selected bits therein) and an error bit (or error bits) from the error shift register 153 are loaded into the data snapshot buffer 155 to form an updated data snapshot 160. The divisor value, N, may be any value that yields a desired rate of updated data snapshots, and thus a desired snapshot interval. For example, in one embodiment, N is selected to match the number of data samples within the data snapshot 160 (which may also match the depth of the data shift register 151), so that each distinct set of N data samples loaded into data shift register 151 (and corresponding error sample (E) loaded into register 153) is framed in a respective data snapshot 160. In alternative embodiments, N may be larger or smaller than the number of data samples within the data snapshot 160 so that some incoming data samples are omitted from the data snapshots (i.e., skipped) or included within two or more data snapshots (duplicated). Also, while the snapshot clock signal (CLK/N) and resulting periodic snapshot interval are assumed in embodiments described below, an aperiodic signal (yielding an aperiodic snapshot interval) may be used in alternative embodiments. For example, in one embodiment, a pseudo-random bit sequence generator (PRBS) is used to strobe each new data snapshot into the snapshot buffer 155 (and otherwise replace the CLK/N signal as a timing source), thus avoiding periodicity in the data snapshot interval. In an alternative embodiment, the finite state machine 135 of FIG. 1 or other control circuit may assert the snapshot clock signal or other timing signal on an as-needed basis, thus obtaining new data snapshots 160 on demand.

As discussed in reference to FIG. 1, each data snapshot 160 may be qualified by a validity signal (VS) that indicates whether the data snapshot is valid or invalid. In one embodiment, for example, each data snapshot 160 is indicated to be valid if the data bit that corresponds to the main bit has a state that corresponds to the data level being tracked by an error sampler within the receive circuit 121 of FIG. 1. That is, in one implementation, the error sampler compares the incoming signal with a threshold that corresponds to an expected signal level for a selected state of conveyed data so that, if the incoming signal conveys a data state other than the selected state, then the comparison yields relatively meaningless error information, and the error sample is said to be invalid. More specifically, in one embodiment, the error sampler compares the incoming signal with a logic ‘1’ data level threshold so that, if the incoming signal conveys logic ‘0’ data, an invalid error sample is produced. In such an embodiment, the state of the main tap data indicates whether the error sample is valid or not (e.g., if main data bit matches the logic state of the data level threshold, the error sample is valid) and thus may be used to qualify the validity of the data snapshot as whole. Such an embodiment is depicted in FIG. 2, with the main data bit being output from the snapshot buffer as the validity signal (VS). In alternative embodiments, the validity signal may be a logical function of several data bits. For example, when partial-response signaling is used, the validity signal may be generated by a logical AND of the current and previous data bit to indicate the error captured at the highest level. Also, where multiple error bits are included within the data snapshot, the validity signal may be formed by a logical combination of corresponding data bits. Further, in embodiments in which multiple error samplers are used to compare the incoming signal with each possible data level (e.g., logic ‘1’ and logic ‘0’ data levels in a binary signaling embodiment, and potentially additional data levels in multi-level signaling embodiments), all error samples and corresponding data snapshots may be valid so that the validity signal may be omitted.

FIG. 3 illustrates an embodiment of an update filter 175 that may be used to implement update filter 131 of FIG. 1. Update filter 175 includes a set of update averaging circuits 177₀-177_{T-1} each coupled, for example, to buffer 150 of FIG. 2 to receive the error bit (E) and a respective one of data bits D[0]-D[T−1] from each new data snapshot. As shown in the exemplary detail view of update averaging circuit 177₀, each update averaging circuit 177 in the embodiment of FIG. 3 includes an exclusive-OR gate 179 and a sign/magnitude counter 181 that operate to generate a time-averaged update value according to the sequence of input data and error bits. More specifically, the exclusive-OR gate 179 receives each new data/error bit pair and generates a corresponding update signal 180 that is either high or low according to whether the error bit and data bit match or do not match. Conceptually, each update signal 180 may be viewed as a vote to increase or decrease the tap weight that corresponds to the incoming data bit. For example, in one embodiment, the filtered update values (i.e., outputs of the update filter 175) may be applied in a least-mean-squared update operation that increments or decrements the equalizer tap weight if, on average, the incoming signal level is lower or higher (respectively) than expected. In the particular embodiment shown in FIG. 3, if the incoming signal amplitude exceeds the expected data level (e.g. logic ‘1’ error in a signal that conveys logic ‘1’ data), the data and error signals will have the same state, so that exclusive-OR gate 179 will generate a logic low update signal 180, in effect, voting to decrease the tap weight. Conversely, if the incoming signal amplitude is below the expected data level, the data and error signals will have a different state, yielding a vote to increase the tap weight (i.e., logic high update signal 180). In alternative embodiments, logical associations between error samples and data samples may be different depending on sample polarity.

The update signal 180 is supplied to an up/down input of the counter 181 which, in effect, tallys the increase/decrease votes and generates a filtered output signal UD[t] (where t represents a tap weight index from 0 to T−1) according to the predominant vote. That is, assuming an initially-zero count value, the counter 181 will develop a positive count value if more count-up signals (e.g., logic high update signals) are received than count-down signals, and a negative count value if more count-down than count-up signals are received. Thus, in the embodiment shown, the sign (“sgn”) of the sign-magnitude count is output from the counter 181 as the filtered output signal UD[t], the sign being, for example, high if more increase votes have been counted than decrease votes.

In one embodiment, the validity signal (VS) is supplied to an enable input (en) of the counter 181 to enable counter operation in response to valid data snapshots and to disable counter operation for invalid data snapshots, each count up or down being triggered by transition of the data snapshot clock signal, CLK/N. Also, the counter 181 may be reset (e.g., in response to a reset signal from the FSM or other circuit component) after a given filtered update signal has been latched or otherwise processed within the FSM.

Returning to FIG. 1, because the tap weight adaptation circuit 125 iteratively adjusts equalizer tap weights based on measurements of incoming signal levels, incoming data sequences that are so correlated as to lack a portion of the frequency content or ISI patterns present in random data may bias or distort equalization settings. The correlation detector 129 is provided to generate a measure of correlation between data bits that are applied to generate filtered updates (i.e., tap data bits) and other bits within a given data snapshot. If the correlation measure for a given filtered update value exceeds a correlation threshold, the correlation detector 129 lowers an update enable signal to prevent the filtered update from being applied in a tap weight update operation. That is, the FSM 135 applies or refrains from applying the filtered update according to the state of the update enable signal thus conditionally updating the tap weight.

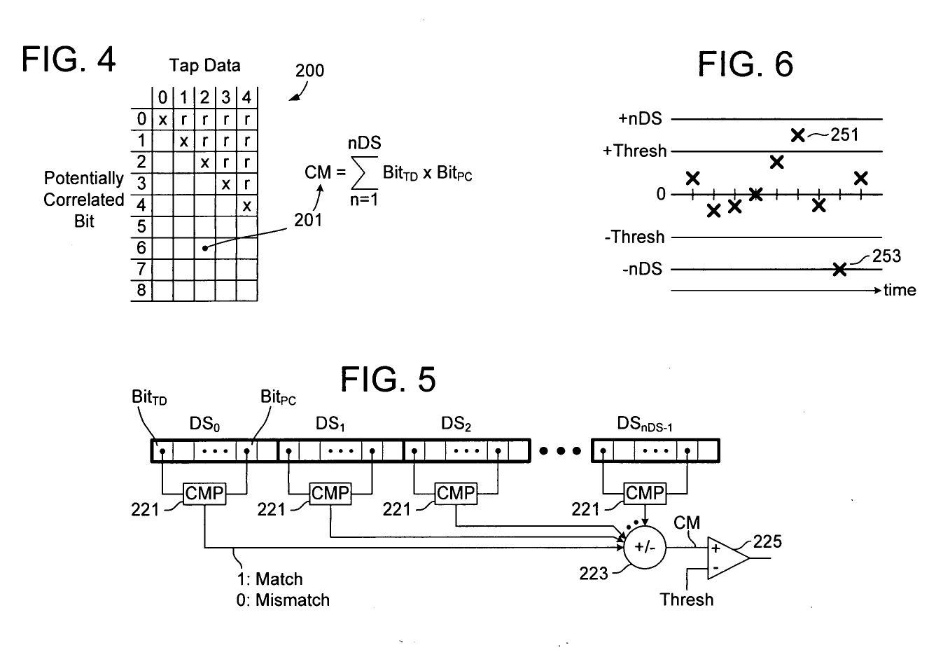

FIG. 4 is a correlation matrix 200 that illustrates a manner of measuring correlation between tap data bits and potentially correlated bits within a sequence of validated data snapshots. Tap data bits (0-4) are presented in the top row of the correlation matrix and bits potentially correlated to the tap data bits (0-8) are listed down the left-hand column so that, except for cells that correspond to the same data bit (i.e., cells having matching row and column indices, marked by ‘x’), each cell in the matrix (i.e., each row/column intersection) represents a respective pair of bit positions within incoming data snapshots at which data correlation may occur. For example, in the first column, tap data bit 0 may be correlated to any or all of bits at bit positions 1-8 within a given sequence of data snapshots. Similarly, in the second column, tap data bit 1 may be correlated to any or all of bits at bit positions 0 and 2-7 within a given sequence of data snap shots, and so forth. Note that the specific numbers of tap data bits and potentially correlated bits shown in FIG. 4 are assumed in a number of embodiments described herein. In all such embodiments, there may be more or fewer tap data bits and/or more or fewer potentially correlated bits, with the data snapshot being adjusted as necessary to capture the potentially correlated bits.

In one embodiment, correlation detector 129 of FIG. 1 generates a correlation measure for each respective pair of bit positions at which data correlation may occur. The correlation measure may be generated in a variety of ways but, in at least some embodiments, indicates a difference between the number of data snapshots that have matching bits at the selected bit positions and the number of data snapshots that have non-matching bits. Assuming, for example, that the logic ‘0’ and ‘1’ states of each tap data bit and potentially correlated bit correspond to values −1 and +1, then a correlation measure may be obtained by multiplying the bit pair obtained from each data snapshot and summing the 201 in FIG. 4 and may be performed in parallel for each potentially correlated pair of bit positions with a data snapshot to generate respective correlation measures. Note that, some pairs of bit positions appear twice in the correlation matrix of FIG. 4 (i.e., the bit pair at row 0/column 1 is the same bit pair as at row 1/column 0, and is thus marked by ‘r’ to indicate its redundancy) and that separate correlation measures need not be generated for redundant pairs of bit positions. Generally, the number of correlation measures needed to cover all non-redundant, potentially correlated bit pairs within the incoming data snapshot may be expressed as M(K−M)+M(M−1)/2, where K is the number of potentially correlated bits and M is the number of tap data bits. In correlation detector embodiments described below, all such correlation measures are generated and compared with a correlation threshold. In alternative embodiments, selected pairs of bit positions may be omitted from correlation measurement (i.e., no correlation measurement generated), for example, to reduce the amount of circuitry required to implement the correlation detector.

FIG. 5 is a conceptual diagram illustrating generation of a correlation measure (CM) and comparison of the correlation measure with a correlation threshold. As shown, a comparison circuit 221 is provided to compare a selected pair of bits within each data snapshot (DS₀-DS_{nDs-1}) with the comparison result (1=Match, 0=Mismatch) being supplied to a correlation counter 223. The correlation counter increments a correlation value in response to each match indication and decrements the correlation value in response to each non-match (i.e., mismatch) indication, so that, after a desired number of data snapshots have been received and evaluated by the comparison circuit 221, the output of the correlation counter constitutes a correlation measure (CM) that may be compared with a correlation threshold (Thresh) in comparator 225.

FIG. 6 illustrates an exemplary sequence of correlation measures that may be generated according to the principles discussed in reference to FIGS. 4 and 5. Assuming that a predetermined number (nDS) of data snapshots are evaluated to generate each correlation measure (marked by ‘X’), a maximum positive correlation measure, +nDS, results when a matching pair of data bits occurs within each of the data snapshots and, conversely, a maximum negative correlation measure, −nDS, results when a non-matching pair of data bits occurs within each of the data snapshots. Thus, a correlation threshold having positive and negative threshold components (+Thresh and −Thresh) may be established within the range bounded by ±nDS. Correlation measures that do not exceed the correlation threshold (e.g., fall within the bounds established by ±Thresh) indicate that the corresponding filtered update values may be applied in tap weight update operations, while correlation measures that exceed the correlation threshold (e.g., correlation measures 251 and 253) indicate that the corresponding filtered update value has been generated based on excessively correlated data and is not to be applied in a tap weight update operation.

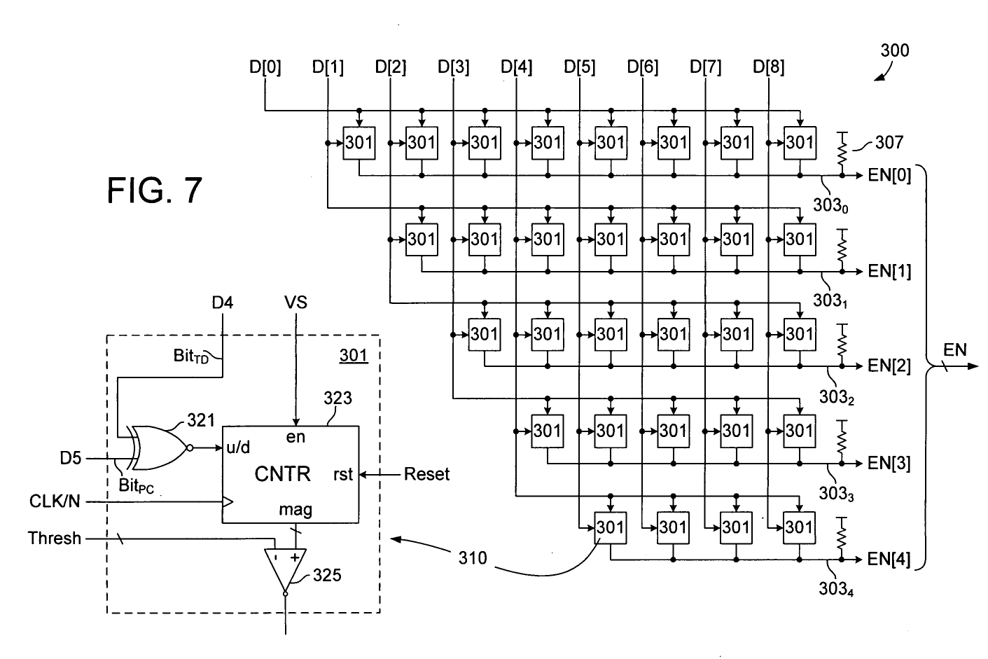

FIG. 7 illustrates an embodiment of a correlation detector 300 that may be used to implement the correlation detector 129 of FIG. 1. The correlation detector 300 includes a set of correlation circuits 301, referred to herein as correlation cells, each of which includes circuitry to generate a correlation measure that represents a time-averaged difference between the number of data snapshots that have matching bits at a predetermined pair of bit positions and the number of data snapshots that have non-matching bits at the predetermined pair of bit positions. In the embodiment shown, the correlation cells 301 are arranged in rows and columns, with the cells of each row coupled to receive a respective tap data bit (D[0]-D[4], respectively) and the cells of each column coupled to receive a respective potentially correlated bit (D[1]-D[8]). By this arrangement, the rows and columns of correlation cells 301 correspond generally to the columns and rows, respectively, of the correlation matrix 200 of FIG. 4.

In one embodiment, the correlation cells 301 of each row have open-drain outputs coupled in common to a respective one of pulled-up enable lines 3030-3034, and are designed to discharge the enable line (i.e., switchably couple the enable line to ground or other logic low reference node) upon detecting excessive bitwise correlation between the input pairs of bits, thereby deasserting the enable signal for the row. A bit-wise OR is effected by this arrangement so that, if one or more of the correlation cells 301 coupled to a given enable line 303 detects excessive correlation (i.e., correlation measure that exceeds a threshold), the enable line 303 is discharged to produce a logic low update enable signal, EN[t], thereby indicating that the corresponding tap data value is excessively correlated to another bit within the data snapshot (and, therefore, that the corresponding filtered update has been generated based on correlated data). If none of the correlation cells 301 coupled to a given row detect excessive correlation, the enable line 303 remains charged to provide a logic-high update enable signal. The enable lines 303₀-303₄ may be pulled-up by respective resistive elements 307 (which may be, for example, active-load elements), precharge circuits or any other circuitry for establishing a desired voltage level on the enable lines 303. Also, in an alternative embodiment, the outputs of the correlation cells 301 of each row may be coupled to respective inputs of a logic gate (e.g., a logic OR gate or logic AND gate) to produce the update enable signal for the row.

In one embodiment, each of the correlation cells 301 includes an exclusive-NOR gate 321 and a correlation counter 323 as shown in detail view 310. The exclusive NOR gate 321 receives the tap data bit and potentially correlated bit at first and second inputs and thus outputs a logic high signal (a match signal) to the up/down input of the correlation counter 323 if the input bits match, and a logic low signal (a non-match signal) to the correlation counter 323 if the bits do not match. In one embodiment, the correlation counter 323 is a sign/magnitude counter that increments or decrements an initially zero difference-count value at the start of each new CLK/N cycle according to the match/non-match condition indicated by the exclusive-NOR output. Thus, after a desired number of data snapshots have been evaluated (e.g. nDS), the count value reflects the difference between the number of matching bits and the number of non-matching bits received within the correlation cell 301, and thus constitutes a difference count that may be used as a correlation measure. More specifically, the magnitude component of the count value may be viewed as an absolute value of the difference and may thus be output from the counter 323 (i.e., as shown by “mag”) and compared with a correlation threshold value to generate the correlation cell output. In one embodiment, the threshold comparison is performed in a logic comparator 325 (i.e., digital value comparator implemented by combinatorial logic) that generates a logic low output if the correlation measure (i.e., the magnitude of the difference count) exceeds the threshold, and an open drain output (or other high impedance state) otherwise. The validity signal (VS) may be supplied to an enable input (en) of the counter 323 to prevent invalid data snapshots from affecting the count value. Also, a reset signal generated by the FSM (i.e., element 135 of FIG. 1) or other circuit component may be used to reset the count value to zero (or other neutral value) after a desired number of data snapshots have been evaluated.

In alternative embodiments, instead of comparing the magnitude of the difference count with a single threshold, the complete sign-magnitude count value maintained within the counter 323 may be compared with respective positive and negative thresholds in comparator 325 (i.e., with the comparator output going low if either threshold is exceeded), thus enabling different threshold values to be programmed for positive and negative correlation. Also, instead of a single counter 323, separate counters may be provided to count match indications and non-match indications, with the outputs of the counters compared with respective positive and negative correlation thresholds. In yet another embodiment, a single counter may be used to count only match indications or non-match indications, with the difference between the number of matching bits and non-matching bits being indicated inferentially. For example, if K bit pairs are compared to generate a given correlation measure, and M matching bit pairs are counted, then the difference between the number of matching bits and non-matching bits is inferentially indicated to be 2M-K. In such an embodiment, the count value, M, may be compared with upper and lower correlation thresholds that bound a tolerable difference between matching and non-matching bits to generate the correlation cell output.

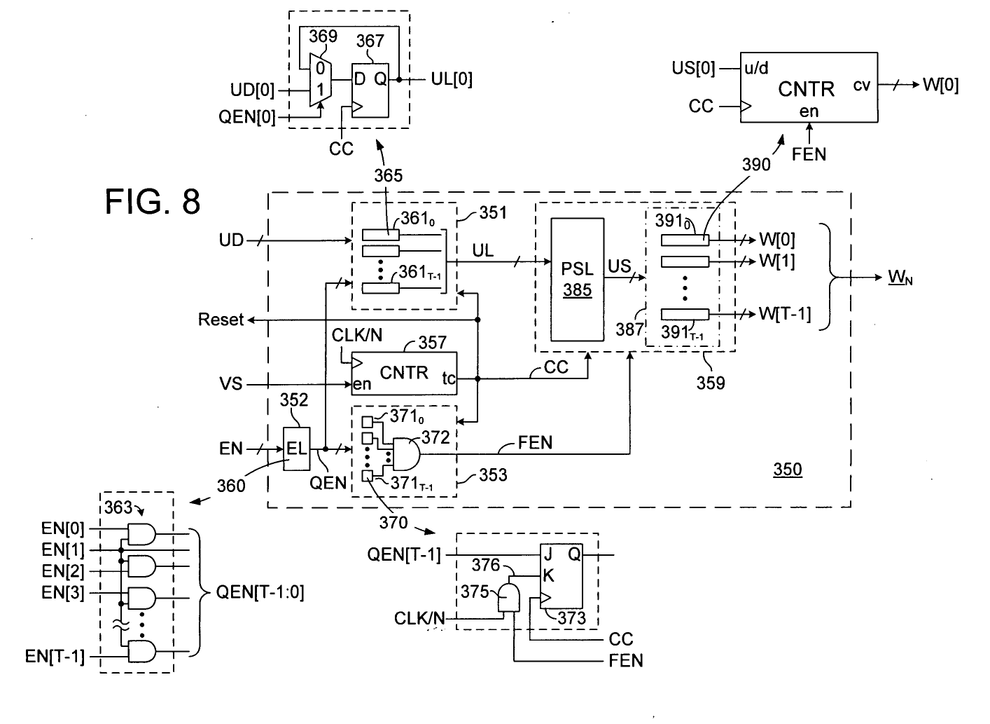

FIG. 8 illustrates an embodiment of a finite state machine 350 that may be used to implement the finite state machine 135 of FIG. 1. The FSM 350 includes an update latch 351, enable logic 352, capture logic 353, snapshot counter 357 and tap weight update logic 359. The snapshot counter 357 is coupled to receive the snapshot clock (CLK/N) at a strobe input and the validity signal (VS) at an enable input, and thus counts the number of valid data snapshots that have been supplied to the update filter and correlation detector. When a desired number of snapshots, nDS, have been received (e.g., when the snapshot counter 357 has reached a terminal count value, tc), the snapshot counter 357 asserts a cycle-complete signal (CC) to mark the end of an evaluation interval and the beginning of a successive evaluation interval. In one embodiment, the snapshot counter 357 is a modulo counter that rolls over to an initial count in the snapshot clock cycle that follows assertion of the cycle-complete signal.

The enable logic 352 is provided to qualify each of the update enable signals EN[T−1:0] according to whether the tap data bit that corresponds to the error sampling instant indicates excessive data correlation. That is, if the tap data bit that corresponds to the error sampling instant exhibits excessive correlation, then the error samples themselves may be biased, thus biasing the entire set of filtered updates. Accordingly, in one embodiment, shown in detail view 360, the enable logic 352 includes a set of AND gates 363 to gate update enable signals EN[0] and EN[2]-EN[T−1] with update enable signal EN[1], the enable signal that corresponds to the main data bit and therefore to the error sampling instant, to produce a set of qualified enable signals QEN[T−1:0] (note that enable signal EN[1] is output directly as qualified enable signal QEN[1]). By this arrangement, if the enable signal that corresponds to the error sampling instant indicates excessive correlation, all of the qualified enable signals will be deasserted. In alternative embodiments, where the error sample is associated with a different tap data bit, a different update enable signal may be used to gate the other update enable signals to produce the qualified enable signals. Also, where multiple error bits are included within each data snapshot, three or more update enable signals may be combined to generate each of the qualified enable signals. In other embodiments, the enable logic 352 may be omitted.

In one embodiment, the cycle complete signal is supplied to the update latch 351 and capture logic 353 to enable filtered update values and qualified enable values, respectively, to be latched therein. The cycle complete signal may also be output from the FSM 350 in the form of a reset signal (Reset) to effect a synchronous or asynchronous reset of counters within the update filter and correlation detector. In the case of asynchronous reset operation, the reset signal may be delayed as necessary to avoid race conditions in latching the filtered update values and corresponding enable values within the FSM 350.

The update latch includes a number of loadable-flop circuits 361₀-361_{T-1} to selectively latch filtered updates (UD) received from the update filter based on whether the corresponding qualified enable signal (QEN) is asserted. Referring to the detail view 365, for example, each loadable-flop circuit 361 includes a multiplexer 369 having an output coupled to the data input of an edge-triggered storage element 367 (e.g., a flip-flop in the example shown, though level-triggered storage elements, such as latches may also be used). One input of the multiplexer 369 is coupled to the storage element output and the other input of the multiplexer 369 is coupled to receive a respective one of filtered update signals UD[0]-UD[T−1]. The control input of the multiplexer 369 is coupled to receive the qualified enable signal that corresponds to the filtered update signal (i.e., one of signals QEN[T−1:0]), and the strobe input of the storage element 367 is coupled to receive the cycle-complete signal (CC) so that, at the completion of each evaluation interval, the storage element 367 is loaded with a new filtered update (UD) if the qualified enable signal is high or maintains its current state (i.e., holds) if the qualified enable signal is low. By this operation, the update latch circuit 351 latches only qualified filtered updates (i.e., filtered updates for which the corresponding qualified enable signals indicate a tolerable (i.e., below-threshold) level of correlation), preserving the contents of each loadable-flop circuit 361 for which the filtered update is disqualified (i.e., qualified enable signal is lowered, indicating excessively correlated data as to the corresponding tap data bit or the tap data bit that corresponds to the error sampling instant).

In one embodiment, the FSM 350 waits to receive a qualified filtered update for each equalizer tap position before updating the equalizer tap weights. Also, assuming that qualified filtered updates have been latched for each equalizer tap position (i.e., a full complement of filtered updates have been latched), one or more of the filtered updates may have been latched in a different evaluation interval than others of the filtered updates. The capture logic 353 is provided to support this operation.

In the embodiment of FIG. 8, the capture logic 353 includes a set of enable-latch circuits 371₀-371_{T-1} each including a J-K flip-flop 373 and a logic gate 375 (i.e., as shown in detail view 370). Each of the J-K flip-flops 373 is coupled to receive a respective one of qualified enable signals QEN[0]-QEN[T−1] at its set input (J), a clear signal 376 at its reset input (K), and the cycle-complete signal (CC) at its strobe input. By this arrangement, each of the enable-latch circuits 371 latches an enabled state (e.g., logic ‘1’ state in this example) if the corresponding qualified enable signal is asserted at the conclusion of an evaluation interval (i.e., when the cycle-complete signal is asserted). The outputs of the enable-latch circuits 371 (i.e., the outputs of the J-K flip-flops 373 therein) are supplied to respective inputs of a logic AND gate 372 which therefore asserts or deasserts a full enable signal (FEN) according to whether enable states have been latched within all the latch-enable circuits 371. In one embodiment, enable states latched within the latch-enable circuits 371 are not cleared until the full-enable signal is asserted (e.g., by ANDing the full enable signal with the snapshot clock to generate clear signal 376) so that, if the full enable signal is not asserted at the conclusion of a given evaluation interval, the state of the latch-enable circuits 371 is carried forward into the next evaluation interval. By this arrangement, multiple evaluation intervals may transpire before the full-enable signal is asserted, with individual filtered updates within the complete set of filtered updates being latched in different evaluation intervals.

In the embodiment of FIG. 8, the full-enable signal is supplied to the tap weight update logic 359 so that, if asserted when the cycle-complete signal is raised, the tap weight update logic 359 is enabled to apply the latched updates (UL) received from the update latch 351 in a tap weight update operation. In one embodiment, the tap weight update circuit 359 includes power scaling logic 385 to scale (i.e., adjust) the tap weight updates in accordance with the present value of the tap weights to avoid exceeding a peak power constraint within the equalizer circuit (e.g., ensuring that a sum of the tap weights remains at or below a fixed or programmed maximum value). The resulting scaled updates (US) are supplied to a tap weight counter bank 387 that includes tap weight counters 391₀-391_{T-1} (one counter for each tap weight). In one embodiment, shown in detail view 390, each of the tap weight counters 391 is an up/down counter coupled to receive a respective scaled update signal (US[0]-US[T−1]) at an up/down input (u/d), the cycle-complete signal at a strobe input, and the full-enable signal at an enable input (en). By this arrangement, when the full enable signal is raised, the tap weight counter responds to assertion of the cycle-complete signal by incrementing or decrementing a tap weight value according to the state of the scaled update, thereby generating an updated tap weight value. The outputs of the tap weight counters 391₀-391_{T-1} thus collectively form an updated tap weight vector W_{N} (where subscript N indicates the number of times the tap weights have been adjusted) which is supplied to equalizer taps within the receive circuit and/or transmit circuit.

It should be noted that numerous changes may be made to the FSM 350 of FIG. 8 in alternative embodiments. For example, instead of waiting to obtain a full set of qualified tap weight updates, the FSM 350 may apply all latched updates (i.e., any qualified tap weight updates) at the end of each evaluation interval, even if qualified tap weight updates are not received for some equalizer taps. In such an embodiment, the capture logic 353 may be omitted and the qualified enable signals (which may be latched in response to the cycle-complete signal) applied to respective enable inputs of the tap weight counters. Also, the loadable flop circuits 361 of the update latch 351 may be replaced by flip-flops or other circuits (i.e., no hold state required, so the multiplexer 369 may be omitted). Further, while tap weight counters 391 for receiver-side tap weights may be disposed within the FSM 350 as shown (or elsewhere in the receive IC), tap weight counters for transmit-side tap weights (e.g., transmit pre-emphasis tap weights) may be disposed within the transmit IC (e.g., in a finite state machine (FSM) or other tap weight logic within the transmit IC) with the scaled updates and signals used to trigger application of the scaled updates (e.g., individual enable signals, or a full-enable signal) output to the transmit IC via a back channel or other communication path. Also, the power scaling logic 385 may be disposed within the transmit IC rather than the receive IC, or may be omitted altogether.

It should be noted that a programmed processor may be used to implement the functions or any subset thereof of the update filter, correlation detector and finite state machine described in reference to FIGS. 1-8. The processor may be formed on the receive IC (i.e., an on-chip processor) or may be formed on a separate integrated circuit die in the same or different integrated circuit package. Also, the processor may generate updated tap weights for multiple receivers and/or transmitters within a given integrated circuit device or set of integrated circuit devices. The processor may be virtually any type of processor including, without limitation, a general purpose processor or special purpose processor (e.g., a microcontroller, digital signal processor (DSP) or the like) and may include an internal program store to store program code that is executed by the processor to perform the above-described conditional tap weight update operations. Alternatively, a separate on-chip or off-chip program store (e.g., a volatile or non-volatile memory, not shown or any other processor or computer-readable media including without limitation, semiconductor memory and magnetic and/or optical media) may be provided and coupled to the processor, for example, via a dedicated or shared bus. The program code stored within the program store may include instructions and/or data that, when executed by the processor, causes the processor to measure correlation between data occurring at selected bit positions within an incoming sequence of data snapshots, then conditionally update corresponding equalizer tap weights according to whether the data correlation exceeds a fixed or programmed threshold.

It should also be noted that the various circuits disclosed herein may be described using computer aided design tools and expressed (or represented), as data and/or instructions embodied in various computer-readable media, in terms of their behavioral, register transfer, logic component, transistor, layout geometries, and/or other characteristics. Formats of files and other objects in which such circuit expressions may be implemented include, but are not limited to, formats supporting behavioral languages such as C, Verilog, and HLDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, non-volatile storage media in various forms (e.g., optical, magnetic or semiconductor storage media) and carrier waves that may be used to transfer such formatted data and/or instructions through wireless, optical, or wired signaling media or any combination thereof. Examples of transfers of such formatted data and/or instructions by carrier waves include, but are not limited to, transfers (uploads, downloads, e-mail, etc.) over the Internet and/or other computer networks via one or more data transfer protocols (e.g., HTTP, FTP, SMTP, etc.).

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process. Section headings have been provided in this detailed description for convenience of reference only, and in no way define, limit, construe or describe the scope or extent of such sections. Also, while the invention has been described with reference to specific embodiments thereof, it will be evident that various modifications and changes may be made thereto without departing from the broader spirit and scope of the invention. Accordingly, the specification and drawings are to be regarded in an illustrative rather than a restrictive sense.

What is claimed is:

1. A method of operation within an integrated circuit device, the method comprising:
receiving a plurality of data values, each data value including a plurality of bits;
generating a first correlation value that indicates a difference between the number of the data values that have matching bits at a first pair of predetermined bit positions, and the number of the data values that have non-matching bits at the first pair of predetermined bit positions; and
conditionally updating a first equalizer tap weight that corresponds to one of the predetermined bit positions based, at least in part, on whether the first correlation value exceeds a first threshold.

2. The method of claim 1 wherein generating the first correlation value comprises counting the data values that have matching bits at the first pair of predetermined bit positions.

3. The method of claim 2 further wherein generating the first correlation value further comprises counting the data values that have non-matching bits at the first pair of predetermined bit positions.

4. The method of claim 3 wherein conditionally updating the first equalizer tap weight based, at least in part, on whether the first correlation value exceeds the first threshold comprises:
comparing a count of the data values that have matching bits at the first pair of predetermined positions with the first threshold value;
comparing a count of the data values that have non-matching bits at the first pair of predetermined positions with the first threshold value; and
refraining from updating the first equalizer tap weight if either (i) the count of the data values that have matching bits exceeds the first threshold or (ii) the count of the data values that have non-matching bits exceeds the first threshold.

5. The method of claim 3 wherein counting the data values that have matching bits comprises incrementing the first correlation value by a first increment and wherein counting the data values that have non-matching bits comprises decrementing the first correlation value by the first increment.

6. The method of claim 5 wherein conditionally updating the first equalizer tap weight based, at least in part, on whether the first correlation value exceeds the first threshold comprises comparing a magnitude of the first correlation value with the first threshold.

7. The method of claim 2 wherein the first threshold comprises an upper threshold value and a lower threshold value, and wherein conditionally updating the first equalizer tap weight based, at least in part, on whether the first correlation value exceeds the first threshold comprises comparing a count of the data values that have matching bits at the first pair of predetermined positions with the upper threshold value.

8. The method of claim 7 wherein conditionally updating the first equalizer tap weight based, at least in part, on whether the first correlation value exceeds the first threshold further comprises comparing the count of the data values that have matching bits with the lower threshold value.

9. The method of claim 8 wherein conditionally updating the first equalizer tap weight base, at least in part, on whether the first correlation value exceeds the first threshold comprises refraining from updating the first equalizer tap weight if the count of the data values that have matching bits exceeds the upper threshold value or is below the lower threshold value.

10. The method of claim 1 further comprising generating a second correlation value that indicates a difference between the number of the data values that have matching bits at a second pair of predetermined bit positions, and the number of the data values that have non-matching bits at the second pair of predetermined bit positions.

11. The method of claim 10 wherein the first pair of predetermined bit positions comprises a first bit position that is common to a first bit position of the second pair of predetermined bit positions, and a second bit position that is different from a second bit position of the second pair of predetermined bit positions.

12. The method of claim 1 further comprising generating additional correlation values that each indicate a difference between the number of the data values that have matching bits at a respective pair of predetermined bit positions, and the number of the data values that have non-matching bits at the respective pair of predetermined bit positions; and
updating the first equalizer tap weight if (i) the first correlation value does not exceed the first threshold and (ii) none of the additional correlation values exceed the first threshold.

13. An integrated circuit device comprising:
a first correlation circuit to receive a plurality of multi-bit data values and to generate a correlation value that indicates a difference between the number of the data values that have matching bits at a first pair of predetermined bit positions, and the number of the data values that have non-matching bits at the first pair of predetermined bit positions; and
a comparator circuit to compare the correlation value with a first threshold value.

14. The integrated circuit device of claim 13 further comprising a signal receiver to generate the plurality of data values in response to a signal received via an external signaling path.

15. The integrated circuit device of claim 13 further comprising a programmable register to store the first threshold value.

16. The integrated circuit device of claim 13 wherein the first correlation circuit comprises a first counter to count the data values that have matching bits at the first pair of predetermined bit positions.

17. The integrated circuit device of claim 16 wherein the first threshold value comprises an upper threshold value and a lower threshold value, and wherein the comparator circuit comprises:
a first comparator to compare a count, received from the first counter, of the data values that have matching bits at the first pair of predetermined positions with the upper threshold value; and
a second comparator to compare the count with the lower threshold.

18. The integrated circuit device of claim 17 wherein the comparator circuit further comprises a logic gate coupled to receive comparison results from the first and second comparators and configured to assert an enable signal if the first comparator indicates that the count is less than the upper threshold and the second comparator indicates that the count is greater than the lower threshold.

19. The integrated circuit device of claim 16 wherein the first correlation circuit further comprises a second counter to count the data values that have non-matching bits at the first pair of predetermined bit positions.

20. The integrated circuit device of claim 19 wherein the comparator circuit comprises:
a first comparator to compare the first threshold value with a count, received from the first counter, of the data values that have matching bits at the first pair of predetermined positions; and
a second comparator to compare the first threshold value with a count, received from the second counter, of the data values that have non-matching bits at the first pair of predetermined positions.

21. The integrated circuit device of claim 16 wherein the first counter comprises an up/down counter to increment a count value by a first increment for each of the data values that has matching bits at the first pair of predetermined bit positions and to decrement the count value by the first increment for each of the data values that has non-matching bits at the first pair of predetermined bit positions.

22. The integrated circuit device of claim 21 wherein the comparator circuit comprises a comparator to compare a magnitude of the count value with the first threshold value.

23. The integrated circuit device of claim 13 further comprising a tap weight update circuit coupled to the comparator circuit and configured to conditionally update a first equalizer tap weight based, at least in part, on whether the comparator circuit indicates that the correlation value exceeds the first threshold value.

24. A signaling system comprising:
a transmitter to transmit a signal;
a receiver to receive the signal and to generate a corresponding plurality of data values;
a correlation circuit to receive the data values from the receiver and to generate a correlation value that indicates a difference between the number of the data values that have matching bits at a first pair of predetermined bit positions, and the number of the data values that have non-matching bits at the first pair of predetermined bit positions; and
a tap weight update circuit to conditionally update an equalization tap weight based, at least in part, on whether the correlation value exceeds a threshold.

25. The signaling system of claim 24 wherein the transmitter comprises an equalization circuit coupled to receive the equalization tap weight from the tap weight update circuit.

26. The signaling system of claim 24 wherein the receiver comprises an equalization circuit coupled to receive the equalization tap weight from the tap weight update circuit.

27. The signaling system of claim 26 wherein the equalization circuit comprises at least one of a linear equalizer and a decision-feedback equalizer.

28. The signaling system of claim 24 wherein the tap weight update circuit comprises:
an update filter to generate a tap weight update value; and
a tap weight storage circuit to adjust the equalization tap weight up or down according to the tap weight update value.

29. The signaling system of claim 24 wherein at least one of the correlation circuit and the tap weight update circuit is implemented, at least in part, by a programmed processor.

30. The signaling system of claim 24 wherein the transmitter comprises a multi-level output driver circuit to transmit, in a respective transmission intervals, symbols that convey more than a single bit.

31. The signaling system of claim 24 wherein the receiver comprises a multi-level sampling circuit to receive, in respective reception intervals, symbols that convey more than a single bit.

32. Computer-readable media having information embodied therein that includes a description of an integrated circuit device, the information including descriptions of:
a first correlation circuit to receive a plurality of multi-bit data values and to generate a correlation value that indicates a difference between the number of the data values that have matching bits at a first pair of predetermined bit positions, and the number of the data values that have non-matching bits at the first pair of predetermined bit positions; and
a comparator circuit to compare the correlation value with a first threshold value.

33. A computer-readable medium having embodied therein one or more sequences of instructions which, when executed by a processing unit, causes the processing unit to:
receive a plurality of multi-bit data values;
generate a first correlation value that indicates a difference between the number of the data values that have matching bits at a first pair of predetermined bit positions, and the number of the data values that have non-matching bits at the first pair of predetermined bit positions; and
conditionally update a first equalizer tap weight that corresponds to one of the predetermined bit positions based, at least in part, on whether the first correlation value exceeds a first threshold.

34. An apparatus comprising:
means for receiving a plurality of data values, each data value including a plurality of bits;
means for generating a first correlation value that indicates a difference between the number of the data values that have matching bits at a first pair of predetermined bit positions, and the number of the data values that have non-matching bits at the first pair of predetermined bit positions; and
means for conditionally updating a first equalizer tap weight that corresponds to one of the predetermined bit positions based, at least in part, on whether the first correlation value exceeds a first threshold.
